(19) United States
(12) Patent Application Publication
(10) Pub. No.: US 2023/0165028 A1
(43) Pub. Date: May 25, 2023

(54) QUANTUM DOT-LIGAND COMPOSITE, PHOTOSENSITIVE RESIN COMPOSITION, OPTICAL FILM, ELECTROLUMINESCENT DIODE, AND ELECTRONIC DEVICE

(71) Applicant: DUK SAN NEOLUX CO., LTD., Cheonan-si (KR)

(72) Inventors: Tae Yun KIM, Cheonan-si (KR); Jong Moon SHIN, Cheonan-si (KR); Changmin LEE, Cheonan-si (KR); Kyung Soo KIM, Cheonan-si (KR)

(73) Assignee: DUK SAN NEOLUX CO., LTD., Cheonan-si (KR)

(21) Appl. No.: 18/053,412

(22) Filed: Nov. 8, 2022

(30) Foreign Application Priority Data
Nov. 22, 2021 (KR) 10-2021-0161630

(51) Int. Cl. H10K 50/115; C09K 11/88; C09K 11/74; C09K 11/71; C09K 11/70; C09K 11/66; C09K 11/64; C09K 11/62; C09K 11/56

(52) U.S. Cl. CPC H10K 50/115; C09K 11/71; C09K 11/562; C09K 11/621; C09K 11/623; C09K 11/625; C09K 11/641; C09K 11/642; C09K 11/643; C09K 11/661; C09K 11/701; C09K 11/703; C09K 11/881; C09K 11/883; C09K 11/885; C09K 11/7407; C09K 11/7414; C09K 11/7421; H10K 2102/351

(57) ABSTRACT

Provided are a quantum dot-ligand composite which includes quantum dots including a semiconductor nanocrystalline core that includes Group III and V elements and a semiconductor nanocrystalline shell that is disposed on the semiconductor nanocrystalline core and includes Group II and VI elements; and organic ligands coordinated to the quantum dots. Additionally, a quantum dot-ligand composite with high luminescence properties and stability according to the electrostatic effective binding ratio between the quantum dots and the organic ligands bound to the surface of the quantum dots, and a photosensitive resin composition, optical film, electroluminescent diode, and electronic device including the same can be provided.

### BACKGROUND OF INVENTION

### Field of the Invention

The present disclosure relates to quantum dots including a core of Groups III and V and a shell of Groups II and VI, organic ligands coordinated to the quantum dots, a photosensitive resin composition, an optical film, an electroluminescent diode, and an electronic device.

### Related Art

A quantum dot (QD) is a semiconductor nano-sized particle, which has a three-dimensionally limited size, in which the size of the particle becomes smaller than the exciton bore radius and shows the quantum confinement effect, and it exhibits new optical and electrical properties that semiconductor materials do not have in a bulk state.

As such properties, the color of the emitted light of quantum dots may vary as the emission wavelength is controlled according to the size of the particles in the same composition. In addition, since quantum dots can emit light not only in the visible ray region but also in various wavelength regions, they have been attracting attention as a material that can be used in next-generation high-brightness light emitting diodes (LEDs), biosensors, lasers, solar cell nanomaterials, etc.

Quantum dots using a Group II-VI semiconductor compound composition consisting of Group II elements and Group VI elements on the periodic table, in particular, quantum dots including cadmium, have high luminous efficiency and photostability, and as a material capable of emitting light in the visible light region, many studies have been conducted on quantum dots until now. However, since cadmium is harmful to the environment and contains toxicity, it can have a harmful effect on the human body when applied to biological fields. Therefore, in recent years, quantum dot materials consisting of Group III-V semiconductor compounds are being actively studied as an environment-friendly and biocompatible quantum dot material that can replace the Group II-VI quantum dots including cadmium.

Unlike internal atoms, surface atoms of quantum dots are in a dangling bond state in which some bonds are cleaved. When another atom or molecule approaches the dangling bond, a chemical bond is easily formed thereat, which induces a surface defect thereby reducing the luminous efficiency. In order to prevent this problem, if an inorganic thin film layer is formed on the quantum dot surface to form a heterogeneous core/shell structure of quantum dots, it is possible to stabilize the chemical stability of the quantum dot surface and maximize the luminous efficiency of the quantum dots.

In addition, when a shell material having an electronically larger band gap than the core is applied to the surface of the core, the effect of confining electrons and holes to the core increases; accordingly, the probability of recombination of quantum dots into excitons can be increased, thereby further improving luminous efficiency. In general, since the band gap of a Group II-VI material that does not include cadmium is relatively large, the material can be appropriately used as a shell material corresponding to a Group III-V core.

In addition, organic ligands may be applied to the surface of the quantum dots consisting of a core and a shell. When organic ligands are coordinated to the surface of quantum dots, the dispersibility of the material is improved by resolving the quantum dot aggregation phenomenon; additionally, like the function of the shells of quantum dots, they can serve to protect the cores from other materials through bonding with the dangling bonds distributed on the surface of the quantum dots, thereby allowing the quantum dots, as a light emitting body, to exhibit higher luminous efficiency and stability.

However, when the amount of the organic ligands coordinated to the surface of the quantum dots is excessively small, surface defects may be generated on the surface of the quantum dots, whereas when the amount is excessively large, the quantum dots may become electrically unstable and their stability may be deteriorated. Therefore, quantum dots having high luminous efficiency and stability can be constituted only by way of linking an appropriate amount of organic ligands to the surface of the quantum dots.

Therefore, it is required that quantum dots be consisted of a Group III-V compound core and a Group II-VI compound shell and an appropriate amount of organic ligands be coordinated to the surface of the quantum dots to thereby improve the luminous efficiency of the quantum dot material.

### SUMMARY

An aspect of the present disclosure provides a quantum dot-ligand composite, which includes quantum dots including a core including Groups III and V and a shell including Groups II and VI; and organic ligands coordinated to the surface of the quantum dots.

Another aspect of the present disclosure provides a quantum dot-ligand composite with high luminescence properties and stability according to the electrostatic effective binding ratio between quantum dots and the organic ligands bound to the surface of the quantum dots.

Additionally, still another aspect of the present disclosure provides a photosensitive resin composition which is capable of forming an optical film with high luminescence properties and stability.

Additionally, still another aspect of the present disclosure provides an optical film with high luminescence properties and stability.

Additionally, still another aspect of the present disclosure provides an electroluminescent diode and an electronic device with high luminescence properties and stability.

The quantum dot-ligand composite according to the present disclosure includes quantum dots including a semiconductor nanocrystalline core that includes Group III and V elements and a semiconductor nanocrystalline shell that is disposed on the semiconductor nanocrystalline core and includes Group II and VI elements; and organic ligands coordinated to the quantum dots;
wherein the quantum dots show a maximum photoluminescence peak in a wavelength region between 500 nm and 650 nm; and
the effective binding ratio (EBR) of the quantum dots and the organic ligands defined by the following [Equation 1] is in the range of 0.1 to 0.6:
$$\text{EBR} = \left|\frac{{C}_{l i g a n d}}{{C}_{Q D}}\right| = \left|\frac{\frac{{m}_{l i g a n d}}{{M}_{l i g a n d}} \times {c}_{l i g a n d}}{\frac{{m}_{Q D}}{{M}_{Q D}} \times {c}_{n e t}}\right|$$
wherein in Equation 1 above:
C_{QD} is the total amount of the positive charge of the quantum dot nanocrystals determined by the inorganic elements constituting the quantum dots;
C_{ligand} is the total amount of the negative charge of the organic ligands bound to the quantum dot surface to electrically stabilize the quantum dots;
m_{ligand} is the mass ratio of the organic ligands to the total amount of the quantum dots and the organic ligands;
m_{QD} is the mass ratio of the inorganic semiconductor nanoparticles constituting the quantum dots to the total amount of the quantum dots and the organic ligands;
M_{QD} is the average molar mass of the quantum dots determined by the inorganic elements constituting the quantum dots;
M_{ligand} is the molecular weight of the organic ligands coordinated to the quantum dots;
cₙₑₜ is the net charge per mole of the quantum dots determined by the inorganic elements constituting the quantum dots; and
C_{ligand} is the amount of charge possessed by the organic ligands in a coordinated state.

It is preferred that the weight ratio of the organic ligands to the inorganic nanoparticles in the quantum dot-ligand composite be in the range of 1.5 to 19.

It is preferred that the average molar mass of the quantum dots derived through the inorganic elements constituting the quantum dots be in the range of 40 g/mol to 100 g/mol.

It is preferred that the molecular weight of the organic ligands coordinated to the quantum dots be in the range of 40 g/mol to 350 g/mol.

It is preferred that the Group III elements of the quantum dots include one or more among In, Ga, and Al.

It is preferred that the Group V elements of the quantum dots include one or more among P, As, Sb, Bi, and N.

It is preferred that the Group II elements of the quantum dots include one or more among Mg, Ca, Zn, Mn, Cu, Co, Hg, and Pb.

It is preferred that the Group VI elements of the quantum dots include one or more among S, Se, and Te.

It is preferred that the quantum dots have a particle diameter in the range of 1 nm to 30 nm.

Still another aspect of the present disclosure provides a photosensitive resin composition including (A) the quantum dot-ligand composite; (B) a photo-crosslinkable monomer; and (C) an initiator.

It is preferred that the photosensitive resin composition include a light diffusion agent.

It is preferred that the photosensitive resin composition include, relative to the total amount of the photosensitive resin composition: 10 wt% to 60 wt% of the quantum dot-ligand composite (A); 30 wt% to 90 wt% of the photo-crosslinkable monomer (B); and 0.1 wt% to 10 wt% of the initiator (C).

According to embodiments of the present disclosure, still another aspect of the present disclosure provides an optical film which includes the quantum dot-ligand composite and has a thickness of 0.005 µm to 500 µm.

According to embodiments of the present disclosure, still another aspect of the present disclosure provides an electroluminescent diode including the optical film.

According to embodiments of the present disclosure, still another aspect of the present disclosure provides an electronic device which includes a display device including the optical film or electroluminescent diode and a control unit for operating the display device.

### Advantageous Effects of the Invention

According to embodiments of the present disclosure, the present disclosure can provide a quantum dot-ligand composite, which includes quantum dots that include a core including Groups III and V and a shell including Groups II and VI; and organic ligands coordinated to the surface of the quantum dot material; additionally, the present disclosure can provide a quantum dot-ligand composite with high luminescence properties and stability according to the electrostatic effective binding ratio between the quantum dots and the organic ligands bound to the surface of the quantum dots, and a photosensitive resin composition, optical film, electroluminescent diode, and electronic device including the same.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a graph showing the maximum photoluminescence peaks of the quantum dots after measuring the photoluminescence wavelength for the quantum dots of Examples 1 to 10 and Comparative Examples 1 to 3 of the present disclosure.

### DESCRIPTION OF EXEMPLARY EMBODIMENTS

Hereinafter, the present disclosure will be described in detail with reference to embodiments of the present disclosure. In describing the present disclosure, if it is determined that a detailed description of a related known constitution or functions thereof may obscure the gist of the present disclosure, the detailed description may be omitted.

When “includes”, “has”, “consists of”, etc. are used in describing the components of the present disclosure, other parts can be added unless “only” is used. When a component is expressed in the singular form, it may include a case in which the plural form is included unless explicitly specified otherwise.

Additionally, in describing the components of the present disclosure, terms such as first, second, A, B, (a), (b), etc. may be used. These terms are only for distinguishing the components from other components, and the essence, order, sequence, number, etc. of the components are not limited by these terms.

In the description of the positional relationship of the components, when two or more components are described as being “connected”, “bound”, “fused”, etc., the two or more components may be directly “connected”, “bound”, or “fused”, but it should be understood that the two or more components may also be “connected”, “bound”, or “fused” by way of a further “interposition” of a different component. In particular, the different component may be included in any one or more of the two or more components that are to be “connected”, “bound”, or “fused” to each other.

Additionally, when a component is described to be “on top” or “on” of another component, it should be understood that this may also include a case where still another component is disposed therebetween as well as a case where the another component is “immediately on top of”. In contrast, when a component is described to be “immediately on top of” another component, it should be understood as indicating that there is no other component disposed therebetween. Additionally, to be “on top” or “on” of the reference part means to be located above or below the reference part, and it does not necessarily mean to be located “on top” or “on” towards the opposite direction of gravity.

In describing the temporal flow relation relevant to components, operation methods, manufacturing methods, etc., for example, when the temporal precedence/posteriority relation or flow precedence/posteriority relation is described by way of “after”, “subsequently”, “thereafter”, “before”, etc., it may also include cases where the flow is not continuous unless terms such as “immediately” and “directly” are used.

Meanwhile, when the reference is made to numerical values or corresponding information for components, the numerical values or corresponding information may be interpreted as including an error range that may occur due to various factors (e.g., procedural factors, internal or external shocks, noise, etc.) even if no additional explicit description is provided.

Additionally, in describing the present disclosure, when a certain part “includes” a certain component, it means that the certain part may further include other components rather than excluding other components unless particularly specified otherwise.

Additionally, in describing the present disclosure, when it comes to “planar phase”, it means when the target part is viewed from the top, and when it comes to “cross-sectional phase”, it means when the cross-section in which the target part is cut vertically is viewed from the side.

As used herein, the term “heteroatom” refers to N, O, S, P, or Si, unless otherwise specified.

Additionally, “heterocyclic group” may also include a ring including SO₂ instead of carbon forming the ring. For example, the “heterocyclic group” may include the following compound.

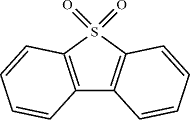 [SMILES: O=S1(=O)c2ccccc2-c2ccccc21]

As used herein, the term “ring” includes monocyclic and polycyclic rings, and includes heterocycles including at least one heteroatom as well as hydrocarbon rings, and may include aromatic and aliphatic rings.

As used herein, the terms “polycyclic” and “polycyclic ring” includes ring assemblies (e.g., biphenyl, terphenyl, etc.), fused multiple ring systems, and spiro compounds, includes aliphatic as well as aromatic, and may include heterocycles including at least one heteroatom as well as hydrocarbon rings.

As used herein, the term “heterocyclic group” includes an aliphatic ring as well as an aromatic ring such as a “heteroaryl group” or “heteroarylene group”, and it means a single ring and a polycyclic ring having 2 to 60 carbon atoms each including one or more heteroatoms unless otherwise specified, but is not limited thereto.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁-₂₀ alkyl group, a C₁-₂₀ alkoxy group, a C₁-₂₀ alkylamine group, a C₁-₂₀ alkylthiophene group, a C₆-₂₀ arylthiophene group, a C₂-₂₀ alkenyl group, a C₂-₂₀ alkynyl group, a C₃-₂₀ cycloalkyl group, a C₆-₂₀ aryl group, a C₆-₂₀ aryl group substituted with deuterium, a C₈-₂₀ arylalkenyl group, a silane group, a boron group, a germanium group, and a C₂-₂₀ heterocyclic group including at least one heteroatom selected from the group consisting of O, N, S, Si, and P, but the substitution is not limited to these substituents.

Additionally, unless otherwise specified, the term “coordination” as used herein means that the hydrogen in a compound coordinated with a compound selected from the group consisting of a C₁-₃₀ alkyl group, a C₂-₃₀ alkenyl group, a C₂-₃₀ alkynyl group, a C₆-₃₀ aryl group, a C₇-₃₀ alkylaryl group, a C₁-₃₀ alkoxy group, a C₁-₃₀ heteroalkyl group, a C₃-₃₀ heteroalkylaryl group, a C₃-₃₀cycloalkyl group, a C₃-₁₅ cycloalkenyl group, a C₆-₃₀ cycloalkynyl group, a C₂-₃₀ heterocycloalkyl group, a halogen (—F, —Cl, —Br, or -I), a hydroxyl group (—OH), a nitro group (—NO₂), cyano group (—CN), an amino group (—NRR′— where R and R′ are each independently a hydrogen or a C₁-₆ alkyl group, an azido group (—N₃), an amidino group (—C(═NH)NH₂), ahydrazino group (—NHNH₂), ahydrazono group (═N(NH₂)), an aldehyde group (—C(═O)H), a carbamoyl group (—C(O)NH₂), a thiol group (—SH), an ester group (—C(═O)OR— where R is a C₁-₆ alkyl group or a C₆-₁₂ aryl group), a carboxyl group (—COOH) or a salt thereof (—C(═O)OM— where M is an organic or inorganic cation), a sulfonic acid group (—SO₃H) or a salt thereof (—SO₃M— where M is an organic or inorganic cation), a phosphoric acid group (—PO₃H₂) or a salt thereof (—PO₃MH or —PO₃M₂— where M is an organic or inorganic cation), or a combined compound selected from an ionized state thereof.

As used herein, the “names of functional groups” corresponding to an aryl group, an arylene group, a heterocyclic group, etc. exemplified as examples of each symbol and a substituent thereof may be described as “a name of the functional group reflecting its valence”, and may also be described as the “name of its parent compound”. For example, in the case of “phenanthrene”, which is a type of aryl group, the names of the groups may be described such that the monovalent group as “phenanthryl (group)”, and the divalent group as “phenanthrylene (group)”, etc., but may also be described as “phenanthrene”, which is the name of its parent compound, regardless of its valence. Similarly, in the case of pyrimidine, it may be described regardless of its valence, or in the case of being monovalent, it may be described as pyrimidinyl (group); and in the case of being divalent, it may be described by the “name of the group” of the valence (e.g., pyrimidinylene (group)). Therefore, as used herein, when the type of substituent is described by the name of its parent compound, it may refer to an n-valent “group” formed by detachment of a hydrogen atom that is bound to a carbon atom and/or hetero atom of its parent compound.

In describing the names of the compounds or the substituents in the present specification, the numbers or letters indicating positions may be omitted. For example, pyrido[4,3-d]pyrimidine may be described as pyridopyrimidine; benzofuro[2,3-d]pyrimidine as benzofuropyrimidine; 9,9-dimethyl-9H-fluorene as dimethylfluorene, etc. Therefore, both benzo[g]quinoxaline and benzo[f]quinoxaline may be described as benzoquinoxaline.

As used herein, an organic electric device may refer to a component(s) between an anode and a cathode, or may refer to an organic light emitting diode including an anode and a cathode, and the component(s) positioned therebetween.

Additionally, in some cases, the organic electric device in the present application may refer to an organic light emitting diode and a panel including the same, or may refer to an electronic device including a panel and a circuit. In particular, for example, the electronic device may include all of a display device, a lighting device, a solar cell, a portable or mobile terminal (e.g., a smart phone, a tablet, a PDA, an electronic dictionary, a PMP, etc.), a navigation terminal, a game machine, various TVs, various computer monitors, etc., but is not limited thereto, and it may be any type of device as long as it includes the component(s).

As used herein, the term “precursor”, which is a chemical substance prepared in advance to react quantom dots, is a concept referring to all of the compounds including metals, ions, elements, compounds, complex compounds, complexes, clusters, etc. It is not necessarily limited to the final substance of a certain reaction, but refers to a substance that can be obtained in any arbitrarily determined step.

Additionally, in describing the present disclosure, the term “Group” refers to a group in the periodic table of elements.

In particular, “Group II” may include Groups IIA and IIB, and Group II elements include Mg, Ca, Zn, Cd, Mn, Cu, Co, Hg, and Pb, but are not limited thereto.

“Group III” may include Groups IIIA and IIIB, and Group III elements include In, Ga, and Al, but are not limited thereto.

“Group V” may include Group VA, and Group V elements include P, As, Sb, Bi, and N, but are not limited thereto.

“Group VI” may include Group VIA, and Group VI elements S, Se, and Te, but are not limited thereto.

The quantum dot-ligand composite of the present disclosure is constituted by a combination of quantum dots including inorganic semiconductor nanoparticles consisting of a core and a shell; and organic ligands coordinated to the surface of the quantum dots, and it is rendered with unique light emitting properties according to the composition and size through the quantum confinement effect.

The quantum dots according to an embodiment of the present disclosure can achieve improved luminescence properties and stability at the same time without including toxic cadmium. In particular, the quantum dot may refer to a single particle or a plurality of particles.

The quantum dot includes a semiconductor nanocrystalline core that includes Group III and V elements and a semiconductor nanocrystalline shell that is disposed on the semiconductor nanocrystalline core and includes Group II and VI elements, and organic ligands coordinated to the surface of the quantum dot. In an embodiment, the quantum dot may have a core-multilayer shell structure which includes a semiconductor nanocrystalline core that includes Group III and V elements and a first shell that is disposed on the core (or on top thereof) and includes Group II and VI elements, a second shell that is disposed on the first shell (or on top thereof) and includes Group II and VI elements.

In an embodiment, the semiconductor nanocrystalline core may include a material selected among a binary compound selected from the group consisting of Group III elements (Al, Ga, and Ti) or a combination thereof and Group V elements (P, As, Sb, Bi, and N) or a combined material thereof (e.g., GaN, GaP, GaAs, GaSb, AlN, AlP, AlAs, AlSb, InN, InP, InAs, InSb, and a mixture thereof); a ternary compound selected from the group consisting of GaNP, GaNAs, GaNSb, GaPAs, GaPSb, AlNP, AlNAs, AlNSb, AlPAs, AlPSb, InNP, InNAs, InNSb, InPAs, InPSb, InGaP, and a mixture thereof; a quaternary compound selected from the group consisting of GaAlNAs, GaAlNSb, GaAlPAs, GaAlPSb,GaInNP, GaInNAs, GaInNSb, GaInPAs, GaInPSb, GaAlNP, InAlNP, InAlNAs, InAlNSb, InAlPAs, InAlPSb, and a mixture thereof, but is not limited thereto.

In an embodiment, the semiconductor nanocrystalline shell may consist of a Group II element and a Group VI element; in which as the Group II element, one selected from the group consisting of Mg, Ca, Zn, Mn, Cu, Co, Hg, and Pb, or a combination thereof may be used; and as the Group VI element, one selected from the group consisting of S, Se, and Te or a combination thereof may be used.

The quantum dot may have a particle diameter of 1 nm to 30 nm, or 5 nm to 15 nm.

The organic ligand is coordinated to the surface of prepared inorganic semiconductor nanoparticles, and it is possible to maintain the electrical neutrality of the quantum dots in the coordination state by taking on a relatively negative charge.

In an embodiment, the organic ligand may include RCOOH, RSH, ROH, RPO(OH)₂, RHPOOH, and R₂POOH (where R is a C₁₋₄₀ substituted or unsubstituted aliphatic hydrocarbon group, preferably a C₃₋₂₄ substituted or unsubstituted aliphatic hydrocarbon group, or a C₆₋₄₀ substituted or unsubstituted aromatic hydrocarbon group, or a combination thereof).

Specific examples of the organic ligand may include C₅₋₂₀ alkylphosphinic acid or C₅₋ ₂₀ phosphonic acid, such as methane thiol, ethane thiol, propane thiol, butane thiol, pentane thiol, hexane thiol, octane thiol, dodecane thiol, hexadecane thiol, octadecane thiol, benzyl thiol; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; phosphonic acid, hexylphosphinic acid, octylphosphinic acid, dodecanephosphinic acid, tetradecanephosphinic acid, hexadecanephosphinic acid, octadecanephosphinic acid; etc., but is not limited thereto. The organic ligand may be used alone or as a mixture of two or more.

In an embodiment, the molecular weight of the organic ligand is 40 g/mol to 350 g/mol, preferably 50 g/mol to 330 g/mol, and more preferably 60 g/mol to 300 g/mol.

Unless otherwise defined in the present disclosure, the “net charge” refers to the total amount of charges when elements constituting the lattice of the quantum dots are in an ideal ionization state, and may vary depending on the composition of the elements.

A quantum dot material consisting of inorganic elements exhibits a relatively positive charge compared to the organic ligand, and the functional group of the organic ligands bound to the quantum dots exhibits a negative charge. Accordingly, the binding between the quantum dots and organic ligands can be viewed as a binding of materials having opposite charges, and thus, the ratio of the charge values can be related to the quantum dots and the amount of organic ligands bound to the quantum dots.

When the amount of the organic ligands coordinated to the surface of the quantum dots is excessively small, the surface defect of the surface of the quantum dots may be generated, whereas when the amount is excessively large, the surface of the quantum dots may become electrically unstable and the luminous efficiency may be reduced. Therefore, in order to constitute a high-efficiency quantum dot material as a light emitting material, an appropriate amount of quantum dots compared to organic ligands is required, and an appropriate level of effective binding ratio (EBR) that can be derived according to the ratio is required.

The effective binding ratio defined by the following [Equation 1] of the quantum dots in an embodiment is in the range of 0.1 to 0.6:

$$\text{EBR} = \left|\frac{{C}_{l i g a n d}}{{C}_{Q D}}\right| = \left|\frac{\frac{{m}_{l i g a n d}}{{M}_{l i g a n d}} \times {c}_{l i g a n d}}{\frac{{m}_{Q D}}{{M}_{Q D}} \times {c}_{n e t}}\right|$$

wherein in Equation 1 above: C_{QD} is the total amount of the positive charge of the quantum dot nanocrystals determined by the inorganic elements constituting the quantum dots; and C_{ligand} is the total amount of the negative charge of the organic ligands coordinated to the quantum dot surface to electrically stabilize the quantum dots at the same equivalent.

The total amount of the positive charge of quantum dots can be determined by calculation through the average molar mass (M_{QD}) of inorganic semiconductor nanoparticles derived from the element composition and atomic weight of element constituting the quantum dots obtained through mass spectrometry (ICP-OES), the net charge per mole (cₙₑₜ) of the inorganic element, and the mass ratio (m_{QD}) of the inorganic semiconductor nanoparticles among the quantum dot obtained using thermogravimetric analysis (TGA)..

The total amount of the negative charge of the organic ligands can be determined by calculation through the mass ratio (m_{ligand}) of the organic matters obtained through thermogravimetric analysis, the molar mass of the organic ligands (M_{ligand}), and the charge number of the functional groups of the organic ligands (c_{ligand}).

In an embodiment, the average molar mass (M_{QD}) of the quantum dots derived through the inorganic elements constituting the quantum dots is in the range of 40 g/mol to 100 g/mol, preferably 45 g/mol to 90 g/mol, and more preferably 50 g/mol to 70 g/mol.

In an embodiment, the weight ratio of the organic ligands to the inorganic nanoparticles of the quantum dots is in the range of 1.5 to 19, preferably 1.8 to 9, and more preferably 2.3 to 5.7.

In an embodiment, the quantum dots have a maximum photoluminescence peak in the range of about 500 nm to 650 nm, preferably 510 nm to 630 nm, and more preferably 520 nm to 620 nm.

The quantum dots according to an embodiment have the above-described structure, the surface defects of the quantum dot surface are reduced through the effective binding ratio of the organic ligand and the appropriate range, and simultaneously are charge-stable. Accordingly, quantum dots according to an embodiment may be advantageous in their optical properties and stability.

In another aspect, according to embodiments of the present disclosure, a photosensitive resin composition can be provided.

The photosensitive resin composition includes (A) a quantum dot-ligand composite, (B) a photo-crosslinkable monomer, and (C) an initiator.

In describing the photosensitive resin composition according to the embodiments of the present disclosure, since the matter relating to the quantum dot-ligand composite is the same as described for the quantum dot-ligand composite according to the embodiments of the present disclosure described above unless otherwise specifically described, it will be omitted.

The photosensitive resin composition may include 10 wt% to 60 wt% of the quantum dot-ligand composite relative to the total amount of the photosensitive resin composition. The lower limit of the content of the quantum dot-ligand composite may be 20 wt% or more or 30 wt% or more. The upper limit of the content of the quantum dot-ligand composite may be 60 wt% or less. When the photosensitive resin composition includes the composite in the above-mentioned content, it may have a viscosity suitable for coating and inkjetting while having a sufficient luminescent effect.

A photo-crosslinkable monomer may be a monofunctional ester of (meth)acrylic acid having one ethylenically unsaturated double bond or polyfunctional ester of (meth)acrylic acid having at least two ethylenically unsaturated double bonds. The polyfunctional ester may be, for example, a difunctional ester, a trifunctional ester, or a tetrafunctional ester.

In the present disclosure, the photo-crosslinkable monomer one type of monomer may be used or two or more types may be used in combination.

The photo-crosslinkable monomer, by having the above ethylenically unsaturated double bond, can cause sufficient polymerization when exposed during a pattern formation process, to thereby form a pattern with excellent heat resistance, light resistance, and chemical resistance.

Specific examples of the photo-crosslinkable monomer may include, as a monofunctional ester, ethylene glycol methacrylate, methyl methacrylate, ethyl methacrylate, isopropyl methacrylate, N-butyl methacrylate, t-butyl methacrylate, hexyl methacrylate, ethylhexyl methacrylate, lauryl methacrylate, octyl methacrylate, cyclohexyl methacrylate, benzyl methacrylate, tetracyclodecyl methacrylate, N-phenylmaleimide, N-cyclohexyl maleimide, methacrylic acid, isobomyl methacrylate, styrene, vinyl acetate, vinyl pyrrolidone, etc.; and may include, as a multifunctional ester, ethylene glycol diacrylate, ethylene glycol dimethacrylate, diethylene glycol diacrylate, triethylene glycol diacrylate, triethylene glycol dimethacrylate, 1,6-hexanediol diacrylate, 1,6-hexanediol dimethacrylate, propylene glycol diacrylate, propylene glycol dimethacrylate, dipropylene glycol diacrylate, dipropylene glycol dimethacrylate, tripropylene glycol diacrylate, tripropylene glycol dimethacrylate, pentaerythritol triacrylate, dipentaerythritol pentaacrylate, dipentaerythritol hexaacrylate, bisphenol A epoxy acrylate, ethylene glycol monomethyl ether acrylate, trimethylolpropane triacrylate, etc., and multi-acrylates to which an ethyleneoxy group or γ- or ε-lactone chain is linked, but the monofunctional esters and polyfunctional esters of the photocrosslinkable monomer are not limited thereto.

Examples of commercially available products of the photo-crosslinkable monomer are as follows.

Examples of the bifunctional ester of (meth)acrylic acid may include Aronix M-210, M-240, M-6200, etc. of Toagosei Kagaku Kogyo Co., Ltd.; KAYARAD HDDA, HX-220, R-604, etc. of Nihon Kayaku Co., Ltd., etc.; and V-260, V-312, V-335 HP, V-1000, V-802, etc. of Osaka Yuki Kagaku Kogyo Co., Ltd.

Examples of the trifunctional ester of (meth)acrylic acid may include Aronix M-309, M-400, M-405, M-450, M-7100, M-8030, M-8060, etc. of Toagosei Kagaku Kogyo Co., Ltd.; KAYARAD TMPTA, DPCA-20, DPCA-60, DPCA-120, etc. of Nihon Kayaku Co., Ltd., etc.; and V-295, V-300, V-360, etc. of Osaka Yuki Kagaku Kogyo Co., Ltd.

The photo-crosslinkable monomer may be used after treating with an acid anhydride so as to provide more excellent developability. The photo-crosslinkable monomer may be included in an amount of 30 wt% to 90 wt% or 35 wt% to 85 wt% relative to the total amount of the photosensitive resin composition. When the photo-crosslinkable monomer is included within the above range, the quantum dots and the initiators can be sufficiently added thereinto, thereby having a sufficient amount of light emission and exhibiting high reliability.

The photosensitive resin composition may further include a binder resin.

The binder resin may be one or more selected from the group consisting of an acrylic resin and an epoxy resin.

As the initiator, one or more selected from a photopolymerization initiator and a thermal polymerization initiator may be used.

As the photopolymerization initiator, for example, one or more selected from an acetophenone-based compound, a benzophenone-based compound, a thioxanthone-based compound, a benzoin-based compound, an oxime ester-based compound, a phosphorus-based compound, and a triazine-based compound may be used.

Examples of the acetophenone-based compound may include 2,2′-diethoxy acetophenone, 2,2′-dibutoxy acetophenone, 2-hydroxy-2-methylpropiophenone, p-t-butyltrichloroacetophenone, p-t-butyldichloro acetophenone, 4-chloro acetophenone, 2,2′-dichloro-4-phenoxy acetophenone, 2-methyl-1-(4-(methylthio)phenyl)-2-morpholinopropane-1-one, 2-benzyl-2-dimethylamino-1-(4-morpholinophenyl)-butan-1-one, etc.

Examples of the benzophenone-based compound may include benzophenone, benzoyl benzoic acid, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-crolthioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethyl ketal, etc.

Examples of the oxime ester compound may include 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-a-oxyamino-1 -phenylpropan-1 -one, 2-dimethylamino-2-(4-methylbenzyl)-1-(4-morpholin-4-yl-phenyl)-butan-1-one, 1-(4-phenylsulfanylphenyl)-butan-1,2-di one2-oxi me-O-benzoate, 1-(4-phenylsulfanylphenyl)-octane-1,2-di one2-oxime-(O-benzoate, 1 -(4-phenylsulfanylphenyl)-octan-1 -oneoxime-O-acetate, 1 -(4-phenylsulfanylphenyl)-butan-1 -oneoxime-O-acetate, 1 -(4-methylsulfanyl-phenyl)-butan-1 -oneoxime-O-acetate, hydroxyimino-(4-methylsulfanyl-phenyl)-acetic acid ethyl ester-O-acetate, hydroxyimino-(4-methylsulfanyl-phenyl)-acetic acid ethyl ester-O-benzoate, etc.

Examples of the phosphorus-based compound may include diphenyl(2,4,6-trimethylbenzoyl)phosphine oxide, benzyl(diphenyl)phosphine oxide, diphenyl(2,4,6-trimethylbenzoyl)phosphine oxide, etc.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine; 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphtho 1 -yl)-4,6-bis(trichloromethyl)-s-triazine, 2-(4-methoxynaphthol-yl)-4.6-/)/.s(trichloromethyl)-s-triazine, 2-4-trichloromethyl(piperonyl)-6-triazine, 2-4-trichloromethyl(4′-methoxystyryl)-6-triazine, etc.

As the photopolymerization initiator, a carbazole-based compound, a diketone-based compound, a sulfonium borate-based compound, a diazo-based compound, an imidazole-based compound, a biimidazole-based compound, etc. may be used in addition to the compounds described above.

As the thermal polymerization initiator, a peroxide-based compound, an azobis-based compound, etc. may be used.

Examples of the peroxide-based compound may include ketone peroxides (e.g., methyl ethyl ketone peroxide, methyl isobutyl ketone peroxide, cyclohexanone peroxide, methylcyclohexanone peroxide, acetylacetone peroxide, etc.); diacyl peroxides (e.g., isobutyryl peroxide, 2,4-dichlorobenzoyl peroxide, o-methylbenzoyl peroxide, bis-3,5,5-trimethylhexanoyl peroxide, etc.); hydroperoxides (e.g., 2,4,4,-trimethylpentyl-2-hydroperoxide, diisopropylbenzenehydroperoxide, cumene hydroperoxide, t-butylhydroperoxide, etc.); dialkyl peroxides (e.g., dicumyl peroxide, 2,5-dimethyl-2,5-di(t-butylperoxy)hexane, 1,3-bis(t-butyloxyisopropyl)benzene, t-butylperoxyvalerate n-butyl ester, etc.); alkyl peresters (e.g., 2,4,4-trimethylpentyl peroxyphenoxyacetate, α-cumyl peroxyneodecanoate, t-butyl peroxybenzoate, di-t-butyl peroxytrimethyl adipate, etc.); percarbonates (e.g., di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, t-butyl peroxyaryl carbonate, etc.).

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleic acid), etc.

The initiator may be used together with a photosensitizer that causes a chemical reaction by absorbing light to enter an excited state and then transferring the energy.

Examples of the photosensitizer may include tetraethylene glycol bis-3-mercaptopropionate, pentaerythritol tetrakis-3-mercaptopropionate, dipentaerythritol tetrakis-3-mercaptopropionate, etc.

The content of the initiator may be in an amount of 0.1 wt% to 10 wt% or 0.1 wt% to 8 wt% relative to the total amount of the photosensitive resin composition. When the content of the initiator satisfies the above range, curing occurs sufficiently during exposure or heating in the pattern forming process using the photosensitive resin composition and thus the photosensitive resin composition can obtain excellent reliability, have excellent heat resistance, light resistance, and chemical resistance of the pattern, and also have excellent resolution and adhesion; additionally, the photosensitive resin composition can prevent a decrease in transmittance due to unreacted initiators.

The photosensitive resin composition may further include a light diffusion agent, for example, the light diffusion agent may include barium sulfate, calcium carbonate, titanium dioxide, zirconia, or a combination thereof.

In this case, the content of the light diffusion agent may be in an amount of 0.1 wt% to 10 wt% or 0.1 wt% to 8 wt% relative to the total amount of the photosensitive resin composition. When the content of the light-diffusion agent satisfies the above-described range, it may have a viscosity suitable for coating and inkjetting while having a sufficient light-diffusion effect.

In another aspect, according to embodiments of the present disclosure, it is possible to provide an optical film including a semiconductor nanoparticle-ligand composite.

In describing the optical film according to the embodiments of the present disclosure, the matters relating to the nanoparticle-ligand composite are the same as those described regarding the semiconductor nanoparticle-ligand composite according to the above-described embodiments of the present disclosure, unless otherwise specified, and are thus omitted herein.

The optical film may be, for example, a wavelength conversion film or color filter that converts light of a specific wavelength into light of another specific wavelength. For example, the optical film according to embodiments of the present disclosure may be used as a color filter for converting a wavelength of light emitted from a backlight including a light emitting diode, but the optical film according to embodiments of the present disclosure is not limited to the color filter or the wavelength conversion film.

The optical film may be used, for example, as a layer that is positioned between the cathode and anode electrodes of an electroluminescent diode and emits light by electrons and holes arriving from the cathode and anode electrodes.

The optical film may be formed on the bare glass through spin coating, light exposure, or heating process using a photosensitive resin composition. In this case, the spin coating, light exposure, and heating process are merely examples, and the optical film may be formed by any method capable of forming the film without being limited to the spin coating, light exposure, and heating process.

In describing the optical film according to the embodiments of the present disclosure, the matters relating to the photosensitive resin composition are the same as those described regarding the photosensitive resin composition according to the above-described embodiments of the present disclosure, unless otherwise specified, and are thus omitted herein.

The thickness of the optical film may be in the range of 0.005 µm to 500 µm or 1 µm to 11 µm.

In another aspect, according to embodiments of the present disclosure, it is possible to provide an electroluminescent diode including an optical film. The electroluminescent diode may include, for example, a cathode electrode, an anode electrode, and an optical film positioned between the cathode electrode and the anode electrode. The electroluminescent diode may further include one or more among the functional layers consisting of a hole injection layer, a hole transport layer, an electron injection layer, an electron transport layer, etc.

In describing the electroluminescent diode according to the embodiments of the present disclosure, the matters relating to the optical film are the same as those described regarding the optical film according to the above-described embodiments of the present disclosure, unless otherwise specified, and are thus omitted herein.

Since the optical film according to the embodiments of the present disclosure is formed using a semiconductor nanoparticle-ligand composite having excellent compatibility, the electroluminescent diode can have excellent quantum efficiency.

In another aspect, embodiments of the present disclosure can provide an electronic device, which includes a display device including an optical film and a control unit for driving the display device.

In describing the electronic device according to the embodiments of the present disclosure, the matters relating to the optical film are the same as those described regarding the optical film according to the above-described embodiments of the present disclosure, unless otherwise specified, and are thus omitted herein.

In the electronic device, the optical film may be used as a wavelength conversion film or a color filter for converting the wavelength. Since the optical film according to the embodiments of the present disclosure is formed using a semiconductor nanoparticle-ligand composite having excellent compatibility, the electronic device according to the embodiments of the present disclosure can have excellent quantum efficiency.

In another aspect, embodiments of the present disclosure can provide an electronic device, which includes a display device including an electroluminescent diode and a control unit for driving the display device.

In describing the electronic device according to the embodiments of the present disclosure, the matters relating to the electroluminescent diode are the same as those described regarding the electroluminescent diode according to the above-described embodiments of the present disclosure, unless otherwise specified, and are thus omitted herein.

The quantum dots can be prepared through the following manufacturing method. The precursor of each element constituting the quantum dot is reacted by heating it to a specific temperature in a vacuum or N2 atmosphere in a reaction solvent. The corresponding temperature is preferably in the range of 100° C. to 350° C.

Hereinafter, Synthesis Examples of the compound and Preparation Examples of the electrical device according to the present disclosure will be described in detail with reference to examples, but the present disclosure is not limited to the following examples.

### EXAMPLES

### ICP Analysis

Inductively Coupled Plasma Spectroscopy (ICP-OES) was performed using the Agilent Technologies 5100 ICP-OES.

### Thermogravimetric Analysis

A thermogravimetric analysis was performed using the TA Instrument Q50 Thermogravimetirc Analyzer.

### Quantum Efficiency Analysis

Quantum efficiency values of the quantum dots manufactured at a wavelength of 450 nm were obtained using the PL QY spectrometer, Otsuka QE-2100 (OTSUKA Electronics Co., Ltd.).

### Photoluminescence Analysis

The photoluminescence spectrum of the manufactured quantum dots at a wavelength of 450 nm was obtained using the spectrofluorophotometer, Shimadzu RF-6000.

### Example 1 (Manufacture of InZnP/ZnMgSeS/ZnS Quantum Dots)

1) Indium acetate (0.05 g), zinc acetate (1.14 g), oleic acid (3.7 g), and 1-octadecene (15 mL) were placed in a 50 mL three-necked round flask equipped with a reflux device, and the pressure was maintained at about 0.1 torr using a vacuum pump for 1 hour while heating the flask to 110° C.

2) After removing the vacuum, the resultant was heated to 280° C. while adding N₂ gas thereto. Then, 0.43 g of Tris(trimethylsilyl)phosphine was added thereto at once. After the addition, stirring was performed for 10 minutes.

3) After adding an aqueous solution of 1 M magnesium chloride (0.05 mL) at 150° C., a solution in which selenium (0.17 g) and sulfur (0.07 g) were dissolved in trioctyl phosphine (5 mL) was added to the reactor, and the mixture was stirred for 30 minutes.

4) A solution, in which sulfur (0.07 g) was dissolved in 2 mL of trioctyl phosphine, was added back into the reactor and the mixture was stirred for 10 minutes. After reducing the temperature to 240° C. and maintaining the resultant thereat for 3 hours, the reaction was terminated by cooling the temperature of the reactor to room temperature.

### Example 2 (Manufacture of InZnP/ZnMgSeS/ZnS Quantum Dots)

Quantum dots were obtained in the same way as in Example 1, except that 1.50 g of zinc acetate was used in step 1) of Example 1.

### Example 3 (Manufacture of InZnP/ZnMgSeS/ZnS Quantum Dots)

Quantum dots were obtained in the same way as in Example 1, except that 1.00 g of zinc acetate was used in step 1) of Example 1.

### Example 4 (Manufacture of InZnP/ZnMgSe/ZnS Quantum Dots)

Quantum dots were obtained in the same way as in Example 1, except that sulfur was not used in step 3) of Example 1, but 0.10 g of sulfur was used in step 4).

### Example 5 (Manufacture of InZnP/ZnSeS/ZnS Quantum Dots)

Quantum dots were obtained in the same way as in Example 1, except that an aqueous solution of 1 M magnesium chloride was not used in the step 3) of Example 1.

### Example 6 (Manufacture of InZnP/ZnSe/ZnS Quantum Dots)

Quantum dots were obtained in the same way as in Example 1, except that an aqueous solution of 1 M magnesium chloride and sulfur were not used in step 3) of Example 1, but 0.10 g of sulfur was used in step 4) of Example 1.

### Example 7 (Manufacture of InP/ZnMgSeS/ZnS Quantum Dots)

1) Indium acetate (0.05 g), zinc acetate (0.15 g), oleic acid (0.5 g), and of 1-octadecene (15 mL) were added to a 50 mL three-necked round flask equipped with a reflux device, and heated to 110° C., and the mixture was maintained at about 0.1 torr using a vacuum pump for 1 hour.

2) After removing the vacuum, the resultant was heated to 280° C. while adding N₂ gas thereto. Then, 0.43 g of Tris(trimethylsilyl)phosphine was added thereto at once. After the addition, the mixture was stirred for 10 minutes.

3) After adding an aqueous solution of 1 M magnesium chloride (0.05 mL) at 150° C., a solution in which selenium (0.17 g) and sulfur (0.07 g) were dissolved in trioctyl phosphine (5 mL) was added to the reactor, and the mixture was stirred for 30 minutes.

4) A solution, in which sulfur (0.07 g) was dissolved in 2 mL of trioctyl phosphine, was added back into the reactor and the mixture was stirred for 10 minutes. After reducing the temperature to 240° C. and maintaining the resultant thereat for 3 hours, the reaction was terminated by cooling the temperature of the reactor to room temperature.

### Example 8 (Manufacture of InP/ZnMgSe/ZnS Quantum Dots)

Quantum dots were obtained in the same way as in Example 7, except that sulfur was not used in step 3) of Example 7, but 0.10 g of sulfur was used in step 4) of Example 7.

### Example 9 (Manufacture of InP/ZnSeS/ZnS Quantum Dots)

Quantum dots were obtained in the same way as in Example 7, except that an aqueous solution of 1 M magnesium chloride was not used in step 3) of Example 7, but 0.10 g of sulfur was used in step 4) of Example 7.

### Example 10 (Manufacture of InP/ZnSe/ZnS Quantum Dots)

Quantum dots were obtained in the same way as in Example 7, except that an aqueous solution of 1 M magnesium chloride and sulfur were not used in step 3) of Example 7, but 0.10 g of sulfur was used in step 4) of Example 7.

### Comparative Example 1 (Manufacture of InZnP/ZnMgSeS/ZnS Quantum Dots)

Quantum dots were obtained in the same way as in Example 1, except that 1.00 g of zinc acetate was used in step 1) of Example 1 and 0.10 g of sulfur was used in step 4) of Example 1.

### Comparative Example 2 (Manufacture of InP/ZnSeS/ZnS Quantum Dots)

Quantum dots were obtained in the same way as in Example 7, except that an aqueous solution of 1 M magnesium chloride was not used in step 3) of Example 7 but 0.10 g of sulfur was used in step 4) of Example 7.

### Comparative Example 3 (Manufacture of InZnP/ZnSeS/ZnS Quantum Dots)

Quantum dots were obtained in the same way as in Example 1, except that 0.01 g of copper acetate was used instead of an aqueous solution of 1 M magnesium chloride in step 3) of Example 1.

ICP-OES analysis of the quantum dots obtained in Examples 1 to 10 and Comparative Examples 1 to 3 was performed, and the results are shown in Table 1.

TABLE 1

| | In (mol %) | P (mol %) | Zn (mol %) | Se (mol %) | S (mol %) | Mg (mol %) | Cu (mol %) | MWave |
|---|---|---|---|---|---|---|---|---|
| Example 1 | 2.3 | 1.5 | 55.8 | 26.1 | 14.4 | 0.001 | | 64.8 |
| Example 2 | 3.7 | 3.3 | 52.5 | 27.3 | 13.2 | 0.02 | | 65.4 |
| Example 3 | 3.2 | 2.3 | 51.5 | 24.4 | 18.6 | 0.01 | | 63.3 |
| Example 4 | 3.7 | 3.2 | 53.5 | 26.7 | 12.9 | 0.01 | | 65.5 |
| Example 5 | 3.6 | 3.1 | 53.1 | 26.8 | 13.4 | 0 | | 65.3 |
| Example 6 | 3.3 | 2.7 | 55.7 | 27.3 | 11 | 0 | | 66.2 |
| Example 7 | 11 | 8.9 | 45.3 | 21.8 | 13 | 0.02 | | 64.8 |
| Example 8 | 10.1 | 8.6 | 45.2 | 20.1 | 16 | 0.02 | | 66.4 |
| Example 9 | 9.7 | 7.9 | 44.1 | 21.4 | 16.9 | 0 | | 64.6 |
| Example 10 | 9.6 | 8.2 | 46.8 | 23.1 | 12.3 | 0 | | 66.4 |
| Comparative Example 1 | 2.9 | 2.0 | 48.6 | 23.6 | 22.9 | 0.01 | | 61.7 |
| Comparative Example 2 | 12.2 | 8.3 | 48.7 | 15.2 | 15.6 | 0 | | 65.4 |
| Comparative Example 3 | 28.3 | 23.2 | 22.8 | 22.5 | 3.0 | | 0.08 | 73.4 |

Thermogravimetric analysis of the quantum dots obtained in Examples 1 to 10 and Comparative Examples 1 to 3 was performed, and the results are shown in Table 2.

TABLE 2

| | R_{organic} (wt %) | R_{inorganic} (wt %) |
|---|---|---|
| Example 1 | 18 | 82 |
| Example 2 | 22 | 78 |
| Example 3 | 25 | 75 |
| Example 4 | 19 | 81 |
| Example 5 | 20 | 80 |
| Example 6 | 24 | 76 |
| Example 7 | 18 | 82 |
| Example 8 | 23 | 77 |
| Example 9 | 19 | 81 |
| Example 10 | 20 | 80 |
| Comparative Example 1 | 23 | 77 |
| Comparative Example 2 | 16 | 84 |
| Comparative Example 3 | 29 | 71 |

Quantum efficiency analysis of the quantum dots obtained in Examples 1 to 10 and Comparative Examples 1 to 3 was performed immediately after synthesis and after 30 days, and the results are shown in Table 3.

TABLE 3

| | Net Charge (kC/mol elements) | Effective Binding Ratio | Quantum Efficiency (immediately after synthesis) (%) | Quantum Efficiency (after 30 days) (%) |
|---|---|---|---|---|
| Example 1 | 32.1 | 0.30 | 95.2 | 95.1 |
| Example 2 | 24.4 | 0.26 | 88.5 | 87.5 |
| Example 3 | 19.0 | 0.23 | 84.7 | 84.1 |
| Example 4 | 28.3 | 0.18 | 83.4 | 83.1 |
| Example 5 | 26.3 | 0.21 | 84.6 | 84.5 |
| Example 6 | 35.3 | 0.20 | 85.1 | 84.2 |
| Example 7 | 21.9 | 0.31 | 86.2 | 85.7 |
| Example 8 | 26.4 | 0.26 | 85.8 | 84.9 |
| Example 9 | 16.4 | 0.32 | 83.2 | 83.3 |
| Example 10 | 26.1 | 0.22 | 84.7 | 84.2 |
| Comparative Example 1 | 6.8 | 0.08 | 63.2 | 42.5 |
| Comparative Example 2 | 45.8 | 0.09 | 70.4 | 53.6 |
| Comparative Example 3 | 9.6 | 1.10 | 69.4 | 38.4 |

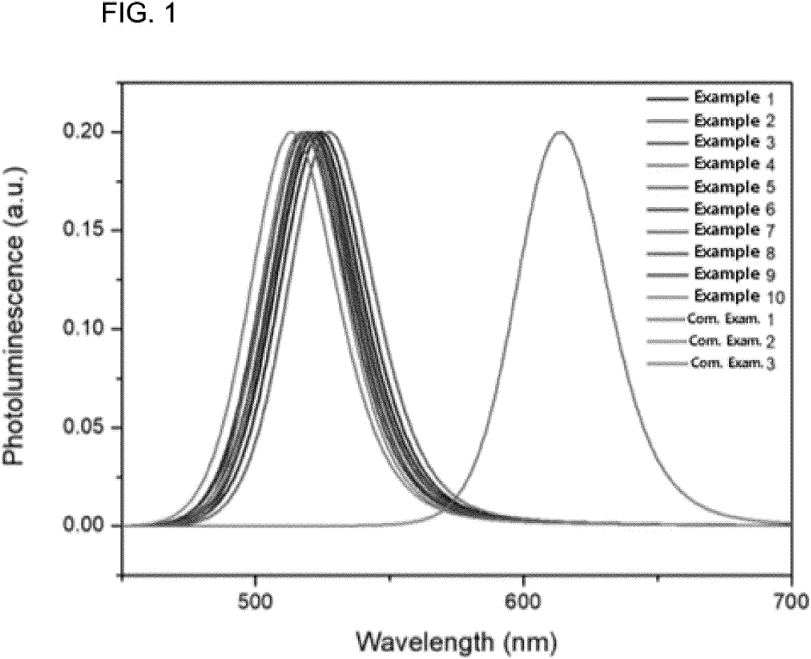

The photoluminescence spectra of the quantum dots obtained in Examples 1 to 10 and Comparative Examples 1 to 3 were measured, and the results are shown in FIG. 1.

Referring to the results of Table 3, it can be seen that the quantum efficiencies in Examples of the present disclosure, in which the effective coupling ratio of quantum dots is included in the range of 0.1 to 0.6, were compared to those of Comparative Examples.

In addition, even in the analysis results of quantum efficiency 30 days after the constitution of quantum dots, comparing Comparative Example 3 and Examples where the effective combination ratio was higher compared to the range of the present disclosure, it can be seen that the stability of the quantum dots is maintained according to the effective binding ratio within the range of the present disclosure.

Regarding the results above, it is speculated that as an appropriate amount of organic ligands are coordinated to the surface of the quantum dots, an effective binding ratio in an appropriate range can be derived, and as a result, the defects in quantum dot surface are inhibited and simultaneously the quantum dots are placed in an electrically stable state, and thereby the quantum efficiency and stability become relatively high.

The above description is merely illustrative of the present disclosure, and those of ordinary skill in the art to which the present disclosure pertains will be able to make various modifications without departing from the essential characteristics of the present disclosure. Accordingly, the embodiments disclosed in the present specification are intended to illustrate, not to limit the present disclosure, and the spirit and scope of the present disclosure are not limited by these embodiments. The protection scope of the present disclosure should be construed by the following claims, and all descriptions within the scope equivalent thereto should be construed as being included in the scope of the present disclosure.

What is claimed is:

1. A quantum dot-ligand composite, which comprises quantum dots comprising a semiconductor nanocrystalline core that comprises Group III and V elements and a semiconductor nanocrystalline shell that is disposed on the semiconductor nanocrystalline core and comprises Group II and VI elements; and organic ligands coordinated to the quantum dots;
wherein the quantum dots show a maximum photoluminescence peak in a wavelength region between 500 nm and 650 nm; and
the effective binding ratio (EBR) of the quantum dots and the organic ligands defined by the following [Equation 1] is 0.1 to 0.6:
$$\text{EBR} = \left|\frac{{C}_{l i g a n d}}{{C}_{Q D}}\right| = \left|\frac{\frac{{m}_{l i g a n d}}{{M}_{l i g a n d}} \times {c}_{l i g a n d}}{\frac{{m}_{Q D}}{{M}_{Q D}} \times {c}_{n e t}}\right|$$
wherein:
C_{QD} is the total amount of the positive charge of the quantum dot nanocrystals determined by the inorganic elements constituting the quantum dots;
C_{ligand} is the total amount of the negative charge of the organic ligands bound to the quantum dot surface to electrically stabilize the quantum dots;
m_{ligand} is the mass ratio of the organic ligands to the total amount of the quantum dots and the organic ligands;
m_{QD} is the mass ratio of the inorganic semiconductor nanoparticles constituting the quantum dots to the total amount of the quantum dots and the organic ligands;
M_{QD} is the average molar mass of the quantum dots determined by the inorganic elements constituting the quantum dots;
M_{ligand} is the molecular weight of the organic ligands coordinated to the quantum dots;
cₙₑₜ is the net charge per mole of the quantum dots determined by the inorganic elements constituting the quantum dots; and
c_{ligand} is the amount of charge possessed by the organic ligands in a coordinated state.

2. The quantum dot-ligand composite of claim 1, wherein the weight ratio of the organic ligands to the inorganic nanoparticles in the quantum dot-ligand composite is 1.5 to 19.

3. The quantum dot-ligand composite of claim 1, wherein the average molar mass of the quantum dots derived through the inorganic elements constituting the quantum dots is 40 g/mol to 100 g/mol.

4. The quantum dot-ligand composite of claim 1, wherein the molecular weight of the organic ligands coordinated to the quantum dots is 40 g/mol to 350 g/mol.

5. The quantum dot-ligand composite of claim 1, wherein the Group III elements of the quantum dots comprise one or more among In, Ga, and Al.

6. The quantum dot-ligand composite of claim 1, wherein the Group V elements of the quantum dots comprise one or more among P, As, Sb, Bi, and N.

7. The quantum dot-ligand composite of claim 1, wherein the Group II elements of the quantum dots comprise one or more among Mg, Ca, Zn, Mn, Cu, Co, Hg, and Pb.

8. The quantum dot-ligand composite of claim 1, wherein the Group VI elements of the quantum dots comprise one or more among S, Se, and Te.

9. The quantum dot-ligand composite of claim 1, wherein the quantum dots have a particle diameter of 1 nm to 30 nm.

10. A photosensitive resin composition comprising:
(A) the quantum dot-ligand composite of claim 1;
(B) a photo-crosslinkable monomer; and
(C) an initiator.

11. The photosensitive resin composition of claim 10, further comprising a light diffusion agent.

12. The photosensitive resin composition of claim 10, wherein the photosensitive resin composition comprises, relative to the total amount of the photosensitive resin composition:
(A) 10 wt% to 60 wt% of the quantum dot-ligand composite;
(B) 30 wt% to 90 wt% of the photo-crosslinkable monomer; and
(C) 0.1 wt% to 10 wt% of the initiator.

13. An optical film comprising the quantum dot-ligand composite of claim 1 and having a thickness of 0.005 µm to 500 µm.

14. An electroluminescent diode comprising the optical film of claim 13.

15. An electronic device comprising:
a display device comprising the optical film of claim 13; and
a control unit for operating the display device.

16. An electronic device comprising:
a display device comprising the electroluminescent diode of claim 14; and
a control unit for operating the display device.
